(19) United States
(12) Patent Application Publication
(10) Pub. No.: US 2007/0069735 A1
(43) Pub. Date: Mar. 29, 2007

(54) Battery sensor and method for the operation of a battery sensor

(75) Inventors: Hans-Michael Graf, Regensburg (DE); Ulrich Hetzler, Dillenburg/Oberscheld (DE)

Correspondence Address: LERNER GREENBERG STEMER LLP, P O BOX 2480, HOLLYWOOD, FL, 33022-2480, US

(73) Assignee: Siemen Aktiengesellschaft

(21) Appl. No.: 10/576,400

(22) PCT Filed: Jul. 11, 2005
(86) PCT No.: PCT/EP05/53303

§ 371 Date: Jun. 12, 2006

(30) Foreign Application Priority Data
Jul. 13, 2004 (DE) 10 2004 033 838.8

(51) Int. Cl. G01R 31/02

(52) U.S. Cl. 324/416

(57) ABSTRACT

A battery sensor has a current meter, an analytical unit, and a microprocessor. During an idle phase, in which the electrical main user, provided with a battery, is switched off, the following steps are carried out. The microprocessor is switched off. At given intervals the measured signal from the current meter is recorded for a given first duration by the analytical unit and allocated first current values which are monitored in the analytical unit for exceeding a first current threshold or dropping below a second current threshold. On exceeding or dropping below the current thresholds, the microprocessor is switched on and, for a given second duration, the measured signal from the current meter is recorded by the analytical unit and allocated second current values which are then analysed in the microprocessor. Procedures for obtaining the electrical charge of the battery by the microprocessor are initiated when a given condition is met, which is dependent on the second current values. The first duration is set smaller than the second duration.

The invention relates to a battery sensor and method for the operation of a battery sensor, comprising an ammeter, an evaluation unit and a microprocessor. Such a battery sensor is used, in particular, in a vehicle and is suitable for determining the operational parameters of a battery, such as, for example, current, voltage and temperature. Modern vehicles have a plurality of electrical consumers, such as, for example, a plurality of motors for electric window units and for adjusting the vehicle seats. Furthermore, a vehicle heater or seat heaters are frequently often provided as electrical consumers.

DE 199 52 693 A1 discloses a method and a device for determining, displaying and/or reading the condition of a battery. The device is designed to determine a battery voltage, a battery temperature, a charge current, a discharge current and an idle current at intervals that remain the same or are dynamically selected. The device has a measuring device for measuring the current and further comprises a microcontroller system that has an AD-converter for analog-digital conversion of the test signals. The microcontroller system has a data memory, in which characteristics of the battery are stored. Furthermore, the test signals that have been determined are further processed in the microcontroller system and thus, for example, a state of charge of the battery is determined. The microcontroller system is connected by a fieldbus to a control interface for the on-board electronics through which the load for electrical consumers can be switched off according to fixed priorities when the charge state is low.

For a reliable operation, in particular of a vehicle, it is important that even after an idle phase, that is, when the main electrical consumers are switched off, the main electrical consumers can again be put into operation in a reliable manner.

DE 689 25 585 B2 discloses a device for depassivating a passivated lithium battery that comprises a first means for what is referred to as momentary short-term drawing of current from the passivated battery in order to effect the depassivation thereof. A second means is provided for monitoring the state of power discharge in the battery and for controlling the first means for momentary drawing of current from the passivated battery until the battery is returned to a useable state of power discharge.

WO 00/62087 A1 discloses a consumer usage device comprising a body that has a mechanical arrangement for fixing to a consumer device and to a battery of the consumer device. The body accommodates an electronic recorder which is designed to record a voltage and/or a current in a battery. In a recording mode, the microprocessor is in an idle state. Periodically, the microprocessor is switched on in order to carry out measurements. Depending on these measurements, a microcontroller can determine whether the device will continue to be in the same operational mode. If this is the case, the device will again be transferred into its idle state.

The publication “Stromsparen—gewusst wie!—Tips zur Reduzierung von Batteriestromen in Mixed-Signal-Controller-Designs” (“How to save power—tips on reducing battery currents in mixed signal controller designs”), Burkhardt, M., Elektronik 22/1999, pages 118 to 124, demonstrates that present day microcontrollers offer a number of functions that lower the power consumption in the inactive mode. In a sleep mode, large parts of a controller are disconnected from the power supply. Furthermore, switching measures that reduce the discharge currents of the battery are disclosed.

The object of the invention is to create a battery sensor and a method for the operation of a battery sensor that allows reliable operation of a battery.

This object is achieved by the features of the independent claims. Advantageous embodiments of the invention are set out in the sub-claims.

The invention is characterized by a method for the operation of a battery sensor, and by a battery sensor that is designed accordingly. The battery sensor comprises an ammeter to determine the current in a battery, an evaluation unit and a microprocessor. During an idle phase, in which the main electrical consumers assigned to a battery are switched off, the following steps are carried out. The microprocessor is directed into a switched-off state. In this way, the electric power consumption of the microprocessor is reduced to a minimum value. At given first time intervals, the test signal from the ammeter is recorded by the evaluation unit for a predeterminable first time duration and first current values are assigned thereto, the values being monitored in the evaluation unit as to whether they exceed a first threshold current and/or drop below a second threshold current. When the current has exceeded or dropped below threshold currents, the microprocessor unit is moved into a switched-on state and, for a given second time duration, the test signal from the ammeter is recorded by the evaluation unit and second current values are assigned thereto and are then evaluated in the microprocessor. Given procedures for maintaining the electrical charge of the battery are initiated by the microprocessor when a given condition, which is a function of the current values determined during the second period, is met. The first time duration is shorter than the second time duration. The first and the second time duration differ preferably by at least one order of magnitude. The current values determined during the first time duration are less precise than the current values determined during the second time duration, since it has become apparent that the current measurement is frequently superimposed by a Gaussian noise, which, in a short-term current measurement, leads to a considerable measuring error or to a more considerable measuring error than in a measurement that lasts longer. By an appropriate selection of the threshold currents, which in a particularly advantageous manner can depend on current values last determined for the second time duration, it can be guaranteed with a low amount of measuring work and consequently likewise using a low amount of electrical energy, that a marked change in the current is detected with sufficient speed. A subsequent determination of the current values for the second time duration then provides a very precise measurement result and can be used in order to estimate the battery's state of charge in a precise manner and optionally carry out procedures to maintain the battery's charge.

In an advantageous embodiment of the invention, the microprocessor is moved into the switched-on state during the idle phase, in given second time intervals, and during the given second time duration, the test signal from the ammeter is recorded by the evaluation unit and second current values are assigned thereto and are then evaluated in the microprocessor. The second time intervals are selected to be greater than the first time intervals, preferably greater by at least one order of magnitude.

As a result, it can be guaranteed in a simple manner that even during the idle phase, current values can be precisely determined regularly, that is corresponding to the second time intervals, and used to determine the battery's present state of charge. Yet, the appropriately large choice of second time intervals guarantees that there is only a slight load on the battery with respect to the idle phase as a whole.

It is further advantageous if an integral of the current is determined over the duration of the idle phase as a function of the second current values. As a function of said integral, conclusions can then easily be drawn regarding the battery's state of charge.

In a further advantageous embodiment of the invention, a wake-up signal is created for a superordinate control unit that can implement procedures to maintain the battery's charge if the integral of the current exceeds a given integral threshold. Thus it is guaranteed firstly that, during the idle phase, the superordinate control unit is in the switched-off state for most of the time and that it therefore does not use any or only a minimum electric input, and secondly that the superordinate control unit is then once again moved into a switched-on state by the wake-up signal and can implement procedures to maintain the battery's charge. The above procedures can include, for example, switching off further consumers, which are also basically in a switched-on state during the idle phase.

According to a further advantageous embodiment of the invention, the battery sensor comprises a voltage divider, which, on the input side, is supplied with the voltage discharged on the battery, and on the output side, is conductively connected to an input on the evaluation unit. A first switch is arranged in series with the voltage divider. In one switch position, the aforementioned switch shuts off the flow of current through the voltage divider and in another switch position it enables the flow of current through the voltage divider. In the idle phase, the first switch is directed into the switch position in which it shuts off the flow of current through the voltage divider. As a result, in a simple manner, in the idle phase, this prevents the constant flow through the voltage divider of a current that has to be made available by the battery.

According to a further advantageous embodiment of the invention, a low power resistor is arranged electrically in parallel with the voltage divider, electrically in series to which a second switch is arranged. In one switch position, the aforementioned switch shuts off a flow of current through the low power resistor and in another switch position it enables the flow of current through the low power resistor. The second switch is directed into the switch position in which it shuts off the flow of current through the voltage divider. Subsequently, the voltage on the output side of the voltage divider is determined as a second voltage value. The second switch is directed into the switch position in which it enables the flow of current through the voltage divider and subsequently determines the voltage on the output side of the voltage divider as a second voltage value. As a function of the first and the second voltage values, a line resistance of an electrically conductive connection is determined between the battery and the voltage divider. In this way, the line resistance can be determined in a simple manner. By means of the line resistance, the voltage values determined by the voltage divider on the output side can be corrected. Thus a precise determination of the voltage discharged across the battery can be guaranteed. The above process steps or a battery sensor that is suitably designed along these lines do not necessarily require there to be an ammeter and corresponding steps to determine the current. Furthermore, it is likewise not necessary for the first switch to be assigned to the voltage divider.

According to a further advantageous embodiment of the invention, the battery comprises at least a first and a second battery. The first and the second battery are electrically arranged in series. A voltmeter is provided to determine the voltage discharged on either the first or the second battery. In the evaluation unit, measured values on the voltmeter are determined at given third time intervals and measured values for the output voltage of the voltage divider representing the voltage discharged on the first and second battery are determined at given fourth time intervals. The third time intervals are greater than the fourth time intervals. Thus both the state of charge of the first battery and of the second battery can be determined in a simple manner. Furthermore, it has proved to be sufficient for the voltage discharged either on the first or second battery to be determined less frequently than the voltage discharged both on the first and on the second battery and yet it is possible for very precise information to be obtained regarding the state of charge of the respective battery. The third time intervals are preferably greater by at least one order of magnitude than the fourth time intervals.

The above advantageous embodiment of the invention can also be used in an advantageous manner irrespective of whether the battery sensor comprises an ammeter.

In a further advantageous embodiment of the invention there is a generator assigned electrically in parallel to the battery and a further voltmeter is provided to determine the voltage discharged on the generator. Measurement values from the further voltmeter are determined in the evaluation unit at given fifth time intervals and measured values for the output voltage of the voltage divider are determined at the given fourth time intervals. The fifth time intervals are greater than the fourth time intervals, preferably by at least one order of magnitude.

Thus the state of both the generator and the battery can be determined in a simple manner. Furthermore, it has proved to be sufficient for the voltage discharged on the generator to be determined less frequently than the voltage discharged on the battery and yet it is possible for very precise information to be obtained regarding the state of the generator.

The above advantageous embodiment of the invention can also be used in an advantageous manner irrespective of whether the battery sensor comprises an ammeter.

In a further advantageous embodiment of the invention, when the voltage drops below a given threshold voltage, given operating parameters of the battery are determined and stored in a non-volatile manner. This can be achieved in an EEPROM, for example, and can then be evaluated after the given threshold voltage has later been exceeded. This makes it possible to make a diagnosis of the reason why the voltage dropped below the threshold voltage.

The above advantageous embodiment of the invention can also be used in an advantageous manner irrespective of whether the battery sensor comprises an ammeter.

Embodiments of the invention are shown below with the aid of the schematic drawings. The drawings show:

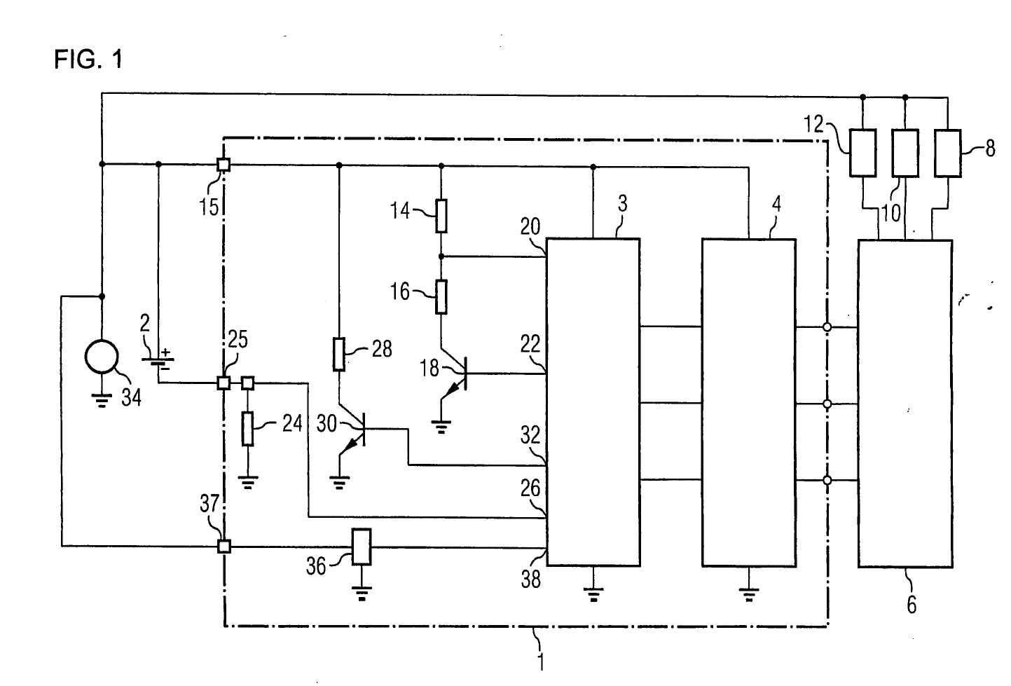

FIG. 1: a first embodiment of a battery sensor,

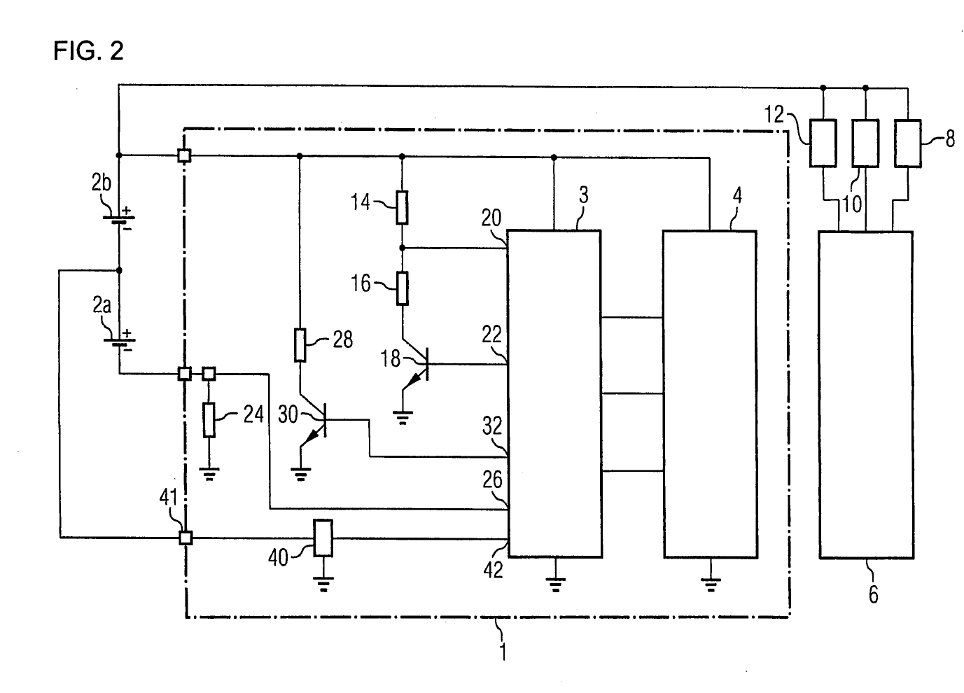

FIG. 2: a second embodiment of a battery sensor,

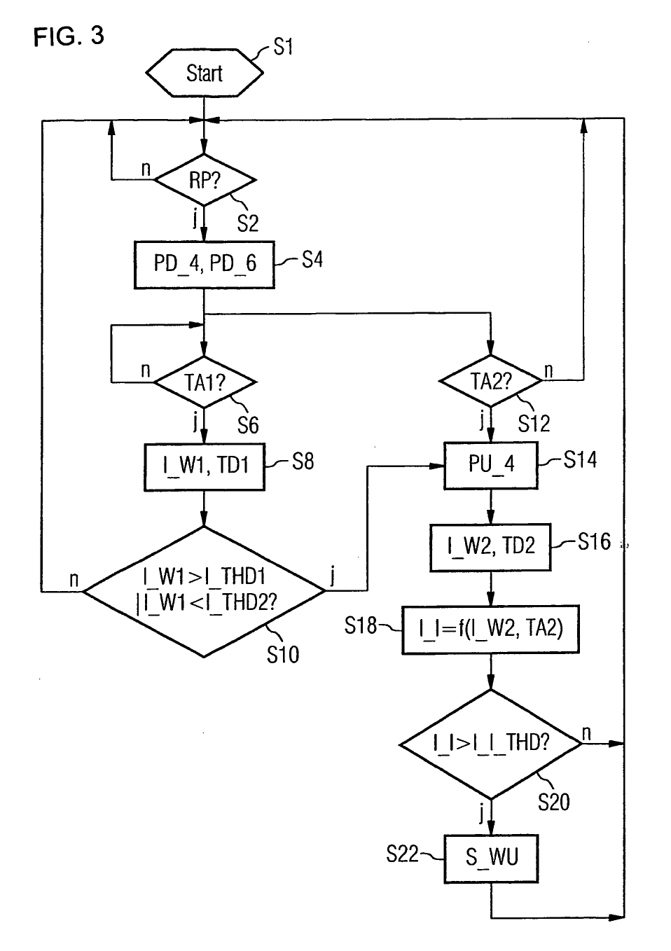

FIG. 3: a flow chart showing a current measuring procedure in the battery sensor,

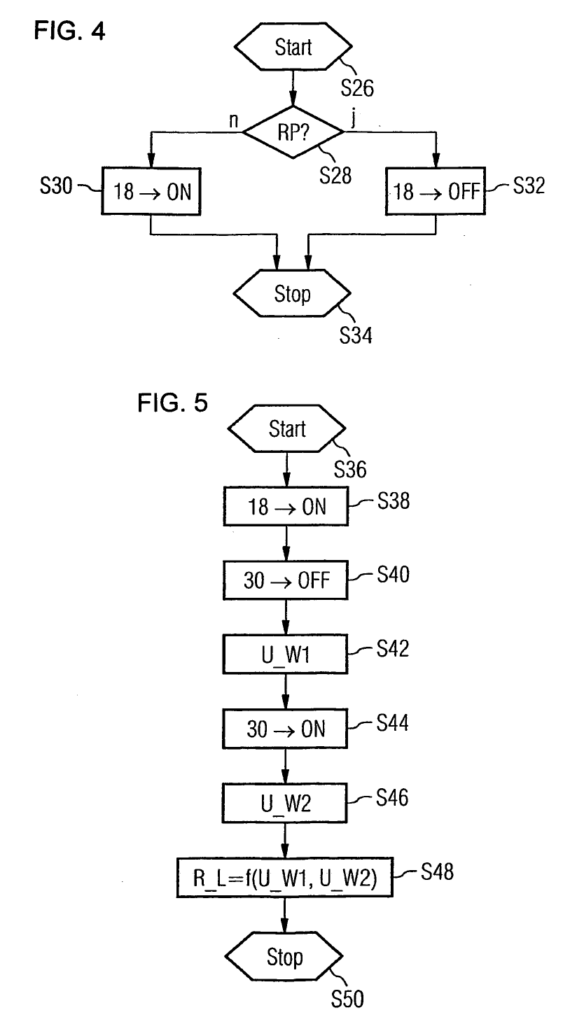

FIG. 4: a flow chart for the operation of a voltage divider in the battery sensor,

FIG. 5: a program for determining a line resistance,

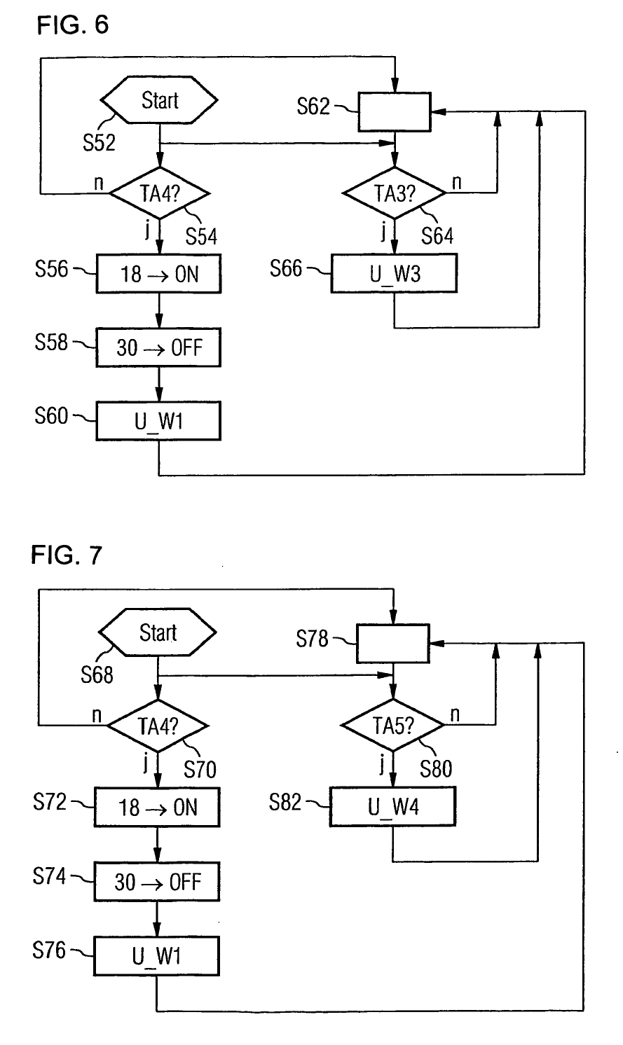

FIG. 6: a flow chart for a program for determining various voltage values,

FIG. 7: a further flow chart for a further program for determining various voltage values and

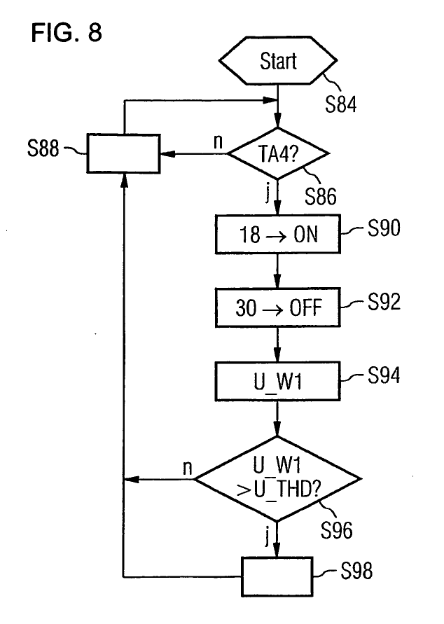

FIG. 8: a flow chart for monitoring a drop in voltage on the battery using the battery sensor.

Elements that have an identical construction or function are shown with the same reference numbers in all the figures.

A battery sensor 1 (FIG. 1) is designed to determine, evaluate and monitor various operating parameters of a battery 2. The battery 2 is preferably a vehicle battery which is arranged in a vehicle, preferably a motor vehicle, and which, on its positive terminal, provides a supply voltage based on a reference potential. The supply voltage can be, for instance, 12, 14, 24, 28, 36 or 48 or a different number of volts.

The battery sensor further comprises an evaluation unit 3, which is preferably an ASIC having a plurality of inputs 20, 26, 38 (FIG. 1), 42 (FIG. 2), a plurality of outputs 22, 32, at least one analog-digital converter, preferably an integral temperature sensor and at least one computing means that is, for example, suitable for carrying out digital filtering of the digitally converted signals that are present at one of the inputs or for carrying out another regular and simple further evaluation of the digitally converted signals. Furthermore, it can also comprise a small memory for the intermediate storage of data. The evaluation unit 3 further comprises a communications interface with a microprocessor 4 to which it is connected in an electrically conductive manner via corresponding signal lines. The microprocessor 4 has a considerably larger memory than the evaluation unit 3 for the storage of data and at least one computing means, which is preferably in a position to carry out considerably more complex computing operations than is possible with the evaluation unit 3.

The battery sensor 1 is preferably assigned to a superordinate control unit 6, with which it can communicate via an interface that is configured in the microprocessor 4. The superordinate control unit 6 is, for example, a control unit for a vehicle electrical system controlling various electrical consumers and in particular the main electrical consumers 8, 10, 12. The electrical consumers can include, for example, adjusting motors to adjust the vehicle seat positions, a vehicle heater, a seat heater, a control device to control one or a plurality of airbags, an engine control unit or actuators for control elements in an internal combustion engine.

The superordinate control unit 6 can therefore be a control unit for a vehicle electrical system but, optionally, it can also be an engine control unit or a different control device. At any rate, the superordinate control unit 6 is designed such that it can turn the electrical consumers on or off either directly or indirectly by issuing appropriate commands to another control device.

The battery sensor 1 comprises a voltage divider that is connected on the input side in an electrically conductive manner to the input 15 of the battery sensor 1. The input 15 of the battery sensor 1 is connected to the positive terminal of the battery 2 in an electrically conductive manner. The voltage divider comprises a first resistor 14 and a second resistor 16 which are electrically connected in series. A switch 18 is further arranged electrically in series with the first and second resistor 14, 16, said switch being preferably designed as a transistor. A node in the electrically conductive connection between the first and second resistor 14, 16 is connected in an electrically conductive manner to the first input 20 of the evaluation unit. A first output 22 is connected in an electrically conductive manner to the first switch 18 such that the first switch 18 enables or shuts off a flow of current through the first and second resistor 14, 16 as a function of the voltage potential at the first output 22.

Furthermore, the battery sensor 1 has an ammeter that comprises an ammeter resistor 24, which can also be referred to as a shunt resistor. The ammeter resistor 24 is designed to have a very low resistance and can, for instance, have a resistance of around 100 μΩ. The ammeter resistor is connected in an electrically conductive manner both to a reference potential and, in an electrically conductive manner, to a negative terminal of the battery 2, that is, via an input 25 of the battery sensor 1. A second input 26 of the evaluation unit 3 is connected in an electrically conductive manner to the ammeter resistor 24 such that the voltage drop on the ammeter resistor 24 is shown on the second input, this voltage then being a measure of the current through the ammeter resistor.

A third resistor 28 is arranged electrically in parallel to the voltage divider, a second switch 30 being arranged electrically in series therewith. The third resistor is designed to have a low resistance and has, for example, a resistance value of 600 Ω. The second switch is preferably designed as a transistor, just like the first switch 18. At its control input, the second switch 30 is connected in an electrically conductive manner to the second output 32 of the evaluation unit 3. Depending on the voltage potential at the second output 32, the second switch 30 shuts off or enables a flow of current through the third resistor 28.

The battery sensor 1 preferably further comprises a voltmeter 36, which is connected via an input 37 in an electrically conductive manner to a generator 34 in such a way that it can determine the voltage drop on the generator 34. The voltmeter 36 is connected in an electrically conductive manner to a third input 38 of the evaluation unit 3. The operation of the battery sensor 1 is further described below in FIGS. 3 to 8 with the aid of the flow charts.

A second embodiment of the battery sensor 1 (FIG. 2) differs from the first embodiment of the battery sensor in that the battery comprises a first battery 2a and a second battery 2b. It can also comprise even more batteries, however. This is frequently the case, for example, in trucks, having a 24 V vehicle electrical system. An input 41 of the battery sensor 1 is connectable in an electrically conductive manner to a node between the two batteries, which are electrically connected in series 2a, 2b. A further voltmeter 40 is connected in an electrically conductive manner to the input 41 of the battery sensor 1. The further voltmeter 40 is further connected in an electrically conductive manner on the output side to a fourth input 42 of the evaluation unit 3. By means of the voltmeter 40, the voltage potential between the first and the second battery 2a, 2b can be determined in relation to the reference potential and then be made available to the evaluation unit 3 at the fourth output thereof 42.

According to the second embodiment, the battery sensor 1 can also comprise the input 37 and the further voltmeter 36 and the third input 38 of the evaluation unit 3 according to the first embodiment. Inputs 20, 26, 42, 38 of the evaluation unit 3 preferably lead in to the AD-converter in the evaluation unit via a multiplexer and amplifier, with the AD-converter then carrying out analog/digital conversion of the signals present and then making the signals available to the computing unit of the evaluation unit 3 for further processing.

The ammeter can also comprise a low-pass filter which is connected upstream of the third input 26 and the time constant thereof is preferably adjustable as a function of whether an idle phase RP is in progress or not. Thus the time constant within the idle phase can be 3s for instance, and outside the idle phase it can be 3 ms. Similarly, a low-pass filter can be assigned to the voltage divider, which is made up of the first and second resistors. Furthermore, corresponding low-pass filters can also be assigned to the voltmeters 36, 40. The voltage divider and the voltmeters 36, 40 can also be integrated with the evaluation unit 3.

The mode of operation of the battery sensor is described hereafter in more detail with the aid of the flow charts in FIGS. 3 to 8. The sequences shown in the flow charts can take place in the evaluation unit 3, but some of them can also take place in the microprocessor 4.

A program for taking a measurement of the current is started in a step S1 (FIG. 3), in which variables are optionally initialized. In a step S2, a check is made as to whether the idle phase RP is in progress, said phase being characterized by the fact that the main electrical consumers 8, 10, 12 are preferably switched off. This can be the case if a vehicle ignition is cut off, for instance, and the ignition key has been removed. If the condition in step S2 has not been met, then it is checked again in step S2, preferably after a given waiting period. If, on the other hand, the condition for step S2 has been met, then in step S4, the microprocessor 4 and the superordinate control unit 6 are directed into their switched-off states PD_4, PD_6. In the switched-off state PD_4, PD_6, the microprocessor 4 and the superordinate control unit 6 do not consume any electrical power or only minimum electrical power.

In a step S6, a check is made as to whether a step S8 was last carried out at a given first time interval TA1 beforehand. If this is not the case, the condition in step S6 is again checked after the given waiting period. If, on the other hand, the condition in step S6 has been met then, in step S8, the first current values I_W1 are determined for a given first time duration TD1. This is achieved by corresponding analog-digital conversion of the voltages present at the second input of the evaluation unit and corresponding conversion into the first current values, as a function of the resistance of the ammeter resistor 24. The first time duration is, for example, about 10 ms. The first time interval TA1 is, for example, about 1 second. The first current values I_W1 are preferably filtered, that is, for example, the mean is taken and then used as the basis of further processing. As a result of the short duration of the measuring time, that is, of the first time duration TD1, a Gaussian noise has a considerable effect on the quality of the first current values I_W1, which consequently only roughly represent the actual value of the current through the battery 2.

In a step S10, a check is made as to whether the first current values I_W1 are greater than a first threshold current I_THD1 and/or the first current values I_W1 are lower than a second threshold current I_THD2. The first and second threshold currents I_THD1, I_THD2 can be firmly fixed in advance, but they can also, for example, be dependent on the last second current values I_W2 that have been recorded. The second current values I_W2 represent the current that is actually flowing through the ammeter resistor 24 in a considerably more precise manner, which will be explained hereafter in even greater detail.

If the condition in step S10 has not been met, the processing is repeated or optionally continued after the given waiting period in step S2. If on the other hand the condition in step S10 has been met, then the processing is continued in a step S14, which will be explained hereafter in greater detail.

The processing of steps S12 and of the following steps runs virtually parallel to steps S6 to S10. In step S12, a check is made as to whether a given second time interval TA2 has elapsed since a step S14 was last processed. If this is not the case, then the processing is again continued in step 2, optionally after the given waiting period has elapsed. If, on the other hand, the condition of step S12 has been met, then the microprocessor 4 is moved into its switched-on state PU_4 in a step S14.

In a subsequent step S16, second current values I_W2 are determined for a given second time duration TD2. The second time interval TA2 can be around 20 minutes for example. The second time duration TD2 can be selected in such way, for example, that a total of around 1000 second current values I_W2 are determined. The second time duration TD2 is, for example, around 250 ms. The evaluation unit 3 typically does not have the memory capacity to provide intermediate storage for all the second current values I_W2 and therefore they are directed by the evaluation unit 3 to the microprocessor 4, which accordingly then digitally filters the second current values I_W2, taking the mean for example. As a result of the plurality of second current values I_W2 that have been determined in this way and of the filtering thereof, the Gaussian noise in the second current values I_W2 that were originally acquired is only an minor factor in the second current values I_W2 that have been filtered in this way and then used as the basis for further processing and it only slightly affects the quality of these values with respect to the actual current flowing through the ammeter resistor 24.

In a step S18, an integral value I_I for the current is determined by integrating the second current values I_W2, which are in each case preferably the mean value taken from the second current values I_W2. The determination of the integral value I_I can be achieved in a particularly simple manner by adding a product of the mean value for the second current values I_W2 and a time duration corresponding to the second time interval TA2 and adding the previous integral value I_I.

Subsequently, in a step S20, a check is made as to whether the integral value I_I for the current is greater than an integral threshold I_I THD. If this is not the case, the processing is continued in step S2, optionally after the given waiting time has elapsed. If, on the other hand, the condition in steps 20 has been met, then when the integral threshold I_I_THD has been appropriately selected, this is an indication that such a large charge has been taken from the battery 2 during the idle phase RP that there is a danger that the charge in the battery 2 could fall below a given minimum charge.

If the condition in step S20 has been met, then in a step S22 a wake-up signal S_WU is produced and redirected to the superordinate control device 6 via the interface of the microprocessor 6. As a function of the wake-up signal S_WU, the superordinate control device 6 is moved from its switched-off state PD_6 into its switched-on state. If the superordinate control device 6 is then in its switched-on state, corresponding data, such as, for example, the integral value I_I for the current or even the second current values I_W2 are transmitted by the microprocessor 4 to the superordinate control device 6. The superordinate control device 6 then initiates corresponding procedures to maintain the charge of the battery, as a function of the second ammeter values I_W2 or even directly as a function of the integral value I_I for the current and optionally further operating parameters of the battery 2, which are then acquired and determined thereafter in the battery sensor in response to commands from the superordinate control device 6. The aforementioned procedures can comprise, for example, switching off electrical consumers which are regularly in a switched-on state even during the idle phases RP.

Subsequent to step S22, the processing is again continued in step S2, optionally after the given waiting period.

A further program is started in a step S26 (FIG. 4). In a step S28, a check is made as to whether the idle phase RP is in progress. If this is not the case, then the first switch 18 is switched on (ON), that is, a flow of current is enabled through the first and second resistors 14 and 16. This again allows measurement of the voltage discharged on the battery 2.

If on the other hand the condition of S28 has been met, that is, if the idle phase RP is in progress, then in a step S32 the first switch is switched off (OFF), that is, a flow of current through the first and second resistors 14, 16 is shut off. In this way it is guaranteed that during the idle phase RP, no current flows through the first and second resistors and consequently a lower discharge of the battery is achieved. Optionally, however, the first switch 18 can be turned off (OFF) at times even outside the idle phase RP.

A further program is started in a step S36. In a step S38, the first switch 18 is turned on (ON). In a step S40, the second switch 30 is turned off (OFF). In a step S42, a first voltage value U_W1 is then determined. Subsequently, the second switch 30 is then turned on (ON) in a step S44. This then has the consequence that the voltage at the positive terminal of the battery 2 initiates a flow of current through the third resistor 28. As the resistor 28 is low-resistance, a now considerably increased current flows from the positive terminal of the battery 2 to the input 15 of the current sensor than when a flow of current is shut off by the third resistor 28. The increased current thus has the consequence that a drop in voltage between the positive terminal of the battery and the input 15 of the current sensor is measurably increased as a function of the line resistance R_L between the positive terminal of the battery 2 and the input 15 of the current sensor.

In a step S46, a second voltage value U_W2 then subsequently undergoes analog/digital conversion at the first input 20 of the evaluation unit 3 by means of the AD-converter.

In a step S48, which is preferably carried out in the microprocessor 4, the line resistance R_L is subsequently determined as a function of the first and second voltage values U_W₁, U_W2 that have been acquired and preferably as a function of the resistance values of the first and second resistors 14, 16. A correction can then be made as a function of the line resistance R_L for subsequent measurements of the voltage on the output side of the voltage divider in order to obtain a more precise value for the voltage discharged across the battery 2.

The method is subsequently terminated in a step S50 and preferably invoked again in a cyclic manner. Steps S38 to S42 can also be run through at a time following steps S44 to S46.

A further program is started in a step S52 (FIG. 6). In a step S54, a check is made as to whether the time interval since the last processing of a step S56 is equivalent to a fourth time interval TA4. If this is not the case, then the processing is continued in a step S62, in which the program preferably pauses for the given waiting period. If, on the other hand, the condition in step S54 is met, then the first switch 18 is switched on (ON) in a step S56. In a step S58, the second switch 30 is switched off (OFF). In a step S60, the first voltage value U_W1 is determined at the first input 20 of the evaluation unit. The first voltage value U_W1 is then made available to the microprocessor 4 for further processing.

The condition in step S64 is checked in a manner that is virtually parallel to steps S54 to S60. In step S64, a check is made as to whether a time interval corresponding to a third time interval TA3 has elapsed since the last time a step S66 was processed. If this is not the case, then the processing is continued in step S62. If this is the case, however, then in a step S66, a third voltage value U_W3 is determined, that is by evaluation of the voltage at the fourth input 42. The third voltage value U_W3 represents the voltage discharged on the first battery 2a. The third time interval TA3 is selected to be considerably shorter, preferably by at least one order of magnitude than the fourth time interval TA4. This, in particular, takes the load off the analog-digital converter in the evaluation unit yet it can still be guaranteed that differences in the charge states of the first and second battery 2a, 2b will be detected.

In step S62, the program is preferably interrupted and other programs serviced during the waiting period in step S62. Subsequent to step S62, the processing is then resumed virtually in parallel in steps S54 and S64.

The program according to FIG. 7 is carried out in the first embodiment of the battery sensor. Steps S68, S70, S72, S74, S76 and S78 correspond to steps S52, S54, S56, S58, S60, S62. Virtually in parallel with step S70, a check is made in a step S80 as to whether the time interval since the last time a step S82 was processed is equal to a fifth time interval TA5. If this is not the case, the processing is continued in step S78. If this is the case, however, a fourth voltage value U_W4 is determined in step S82, said value representing the voltage discharged on the generator 34. The fifth time interval TA5 is preferably selected to be greater, in particular by at least one order of magnitude, than the fourth time interval TA4.

A further program is started in a step S84 (FIG. 8). In a step S86, a check is made as to whether the time interval since the last time a step S86 was processed is equal to a fourth time interval TA4. If this is not the case, the processing is continued in a step S88 in which the program pauses for the given waiting time before the condition of step S86 is checked once again. If on the other hand, the condition for step S86 has been met, the first switch is switched on (ON) in a step S90. In a step S92, the second switch is turned off (OFF). In a step S94, the first voltage value U_W1 is determined.

In a step S96 a check is made as to whether the first voltage value U_W1 drops below a given threshold voltage U_THD. The threshold voltage U_THD is advantageously selected in such a way that, when the voltage drops below it, further operation of the evaluation unit 3, of the microprocessor 4 and/or of the superordinate control unit 6 is no longer possible or only possible to a limited extent. The essential feature is that the threshold voltage U_THD and the fourth time interval TA4 are selected in such a way that, when the condition in step S96 has been met, the evaluation unit 3 and/or the microprocessor 4 are still operable for a given time duration which is still sufficient for given operating parameters of the battery 2 or the batteries 2a, 2b to be determined in a step S98 which will then be carried out and to be stored in a non-volatile memory, such as an EEPROM, for example. These operating parameters can then be fetched and evaluated in an appropriate manner when the microprocessor 4 or the superordinate control device are again operable.

1-14. (canceled)

15. A method for operating a battery sensor, the method which comprises:
providing the battery sensor with an ammeter for determining a battery current, an evaluation unit, and a microprocessor, and performing the following method steps during an idle phase in which main electrical consumers assigned to a battery are switched off:
directing the microprocessor into a switched-off state;
at given first time intervals, acquiring a test signal from the ammeter for a given first time duration with the evaluation unit and assigning thereto first current values, monitoring the values in the evaluation unit to check whether a first threshold current has been exceeded and/or whether a second threshold current has been undershot;
when the first threshold current value is exceeded or the second threshold current is undershot, moving the microprocessor into a switched-on state and acquiring, for a given second time duration, the test signal from the ammeter with the evaluation unit and assigning thereto second current values, and evaluating the values in the microprocessor; and
if certain conditions depending on the second current values are met, initiating given procedures for maintaining an electric charge in the battery by the microprocessor; and
wherein the first time duration is shorter than the second time duration.

16. The method according to claim 15, which comprises, during the idle phase, moving the microprocessor into the switched-on state in given second time intervals greater than the first time intervals and determining with the evaluation unit for the second given time duration the test signal from the ammeter and assigning second current values thereto, and then evaluating the values in the microprocessor.

17. The method according to claim 15, which comprises determining an integral value for the current over the time duration of the idle phase as a function of the respective second current values.

18. The method according to claim 15, which comprises generating a wake-up signal for a superordinate control unit, wherein the superordinate control unit is configured to implement procedures for maintaining the charge in the battery if the integral value for the current exceeds a given integral threshold.

19. The method according to claim 15, wherein the battery sensor comprises a voltage divider having an input side receiving a voltage of the battery and an output side connected to an input of the evaluation unit, a first switch connected electrically in series with the voltage divider and having a first switch position turning off a current flow through the voltage divider and a second switch position enabling the current flow through the voltage divider, and wherein the method further comprises directing the first switch to assume the first switch position during the idle phase to shut off the current flow through the voltage divider.

20. The method according to claim 19, wherein:
a low power resistor is connected in parallel with the voltage divider and in series with a second switch, the second switch having a first switch position shutting off a current flow through the low power resistor and a second switch position enabling the current flow through the low power resistor, and the method further comprises:
directing the second switch into the first switch position shutting off the current flow through the low power resistor and determining the voltage on the output side of the voltage divider as the first voltage value;
directing the second switch into the second switch position to enable the current flow through the low power resistor and determining the voltage on the output side of the voltage divider as a second voltage value; and
determining, as a function of the first and second voltage values, a line resistance of an electrically conductive connection between the battery and the voltage divider.

21. The method according to claim 19, wherein:
the battery includes a first battery and a second battery connected in series and the battery sensor has a voltmeter outputting a measurement signal characteristic of a voltage across either the first battery or the second battery, and the method which comprises:
determining measurement values of the voltmeter at given third time intervals and determining measurement values for the output voltage of the voltage divider at given fourth time intervals, wherein the third time intervals are longer than the fourth time intervals.

22. The method according to claim 19, wherein:
a generator is connected in parallel with the battery and the battery sensor includes a further voltmeter outputting a measurement signal representative of the voltage of the generator, and the method which comprises:
determining measured values from the further voltmeter at given fifth time intervals and determining measured values for the output voltage of the voltage divider at given fourth time intervals, wherein the fifth time intervals are greater than the fourth time intervals.

23. The method according to claim 15, which comprises, when the voltage drops below a given threshold voltage, determining given operating parameters of the battery and storing the parameters in a non-volatile memory.

24. A battery sensor, comprising:
an ammeter for determining a battery current, an evaluation unit, and a microprocessor, configured such that, during an idle phase in which main electrical consumers assigned to a battery are switched off:
said microprocessor is switched off;
said evaluation unit is configured to determine, at given first time intervals, a test signal from said ammeter for a given first time duration, and to assign thereto first current values, said evaluation unit monitoring the values to check whether a first threshold current value has been exceeded and/or whether the current has dropped below a second threshold current value;
when the current has exceeded the first current value or has dropped below the second threshold current value, said microprocessor is placed in a switched-on state and for a given second time duration, the test signal from said ammeter is determined by said evaluation unit and second current values are assigned thereto, the values then being evaluated in said microprocessor;
said microprocessor initiating given procedures for maintaining the electric charge in the battery if a given condition depending on the second current values is met; and
wherein the first time duration is shorter than the second time duration.

25. The battery sensor according to claim 24, which comprises:
a voltage divider having an input side connected to receive a voltage across the battery, and an output side conductively connected to an input of said evaluation unit;
a first switch electrically connected in series with said voltage divider, said first switch having a first switch position shutting off a flow of current through said voltage divider and a second switch position enables the flow of current through said voltage divider.

26. The battery sensor according to claim 25, which comprises:
a low power resistor electrically connected in parallel with said voltage divider;
a second switch electrically connected in series with said low power resistor, said second switch having a first switch position shutting off a flow of current through said low power resistor and a second switch position enabling the flow of current through said low power resistor.

27. The battery sensor according to claim 26, wherein the battery includes first and a second batteries connected in series, and a voltmeter is connected to measure the voltage across either the first or the second battery.

28. The battery sensor according to claim 26, which comprises a generator electrically connected in parallel with the battery and a voltmeter connected to measure a voltage of said generator.
